(19) United States
(12) Patent Application Publication
(10) Pub. No.: US 2025/0004444 A1
(43) Pub. Date: Jan. 2, 2025

(54) Flexible Pin Extensions

(71) Applicant: Taiwan Semiconductor Manufacturing Company, Ltd., Hsinchu (TW)

(72) Inventor: Sachin Kumar, Hsinchu (TW)

(21) Appl. No.: 18/344,095

(22) Filed: Jun. 29, 2023

(51) Int. Cl. G05B 19/4099

(52) U.S. Cl. CPC G05B 19/4099; G05B 2219/45031

(57) ABSTRACT

A method of fabricating an integrated circuit using spare cells is provided. The method comprises receiving an input design and generating a design layout comprising a plurality of functional cells and a plurality of spare cells, wherein the plurality of spare cells comprises a plurality of pins. A plurality of flexible pin extensions are also generated to connect to pins of the plurality of spare cells, wherein the plurality of flexible pin extensions include a plurality of segments formed on different layer levels of the design layout. A routing is performed to interconnect functional cells in the design layout thereby generating a routed design, and an integrated circuit is fabricated according to the routed design.

### BACKGROUND

Integrated circuit (IC) designers often employ an engineering change order (ECO) process to modify a layout at late stages of design closure or after tapeout. To enable functional ECOs, spare cells may be placed at critical locations early in the design flow. These spare cells are incorporated during the placement stage of the design flow and may be placed by the same tools as active cells in the layout, for example using auto place-and-route (APR) tools. Placement of the spare cells is determined based on the design layout and desired functionality of the cells and circuit. After placement, pins of spare cells are tied to power-ground (PG) nets of the layout. Proper placement and design of the spare cells avoids the need to change base layers of the cells during ECO, resulting in more efficient implementation of changes. Even when using spare cells, however, ECOs still result in changes that require costly mask regeneration for modified layers.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic diagram of a spare cell without pin extensions according to an embodiment.

FIGS. 2A and 2B are a schematic diagram of a spare cell including flexible pin extensions according to an embodiment and a flowchart depicting a method of designing a spare cell according to an embodiment.

FIG. 3 is a schematic diagram depicting a flexible pin extension according to an embodiment.

FIG. 4 is a plan diagram depicting a design layout according to an embodiment.

FIG. 5 is a flowchart depicting a design method according to an embodiment.

FIG. 6 is a flowchart depicting a phase of the design method according to an embodiment.

FIG. 7 is a plan diagram depicting an arrangement of spare cells according to an embodiment.

FIG. 8 is a flowchart depicting a phase of the design method according to an embodiment.

FIG. 9 is a schematic diagram depicting segments of a flexible pin extension according to an embodiment.

FIG. 10 is a schematic diagram depicting a segment of a flexible pin extension according to an embodiment.

FIG. 11 is a schematic diagram depicting segments of a flexible pin extension according to an embodiment.

FIGS. 12A and 12B are a flowchart depicting a phase of the design method and a schematic diagram of a spare cell according to an embodiment.

FIGS. 13A and 13B shows plan diagrams depicting design layouts before and after an ECO according to an embodiment and a flowchart depicting a method of designing layouts according to an embodiment.

FIG. 14 is a schematic diagram of a design layout according to an embodiment.

FIG. 15 is a schematic diagram of a spare cell before an ECO and the spare cell after the ECO according to an embodiment.

FIG. 16 is a schematic diagram of a spare cell before an ECO and the sparce cell after the ECO according to an embodiment.

FIG. 17 is a schematic diagram of a spare cell after an ECO according to an embodiment.

FIGS. 18A, 18B, and 18C are block diagrams depicting example systems for implementing approaches described herein for designing integrated circuits.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in some various examples. This repetition is for the purpose of simplicity and clarity and does not in itself dictate a relationship between some various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the circuit. Some of the features described below can be replaced or eliminated for different embodiments. Although some embodiments are discussed with operations performed in a particular order, these operations may be performed in another logical order.

Some integrated circuit designs use fundamental building blocks called cells in order to create complex circuits. Cells may include pre-determined, standard architecture that is selected to provide specific logic or storage functions (e.g. AND gates, OR gates, XOR gates, NOT gates, NAND gates, NOR gates, XNOR gates, flip-flops, inverters, latches). Standard cells may be designed to comprise specific internal arrangements of transistors and other components sufficient to provide the desired pre-determined functions. Designs of different standard cells may be stored in, and recalled from, a library, allowing designers to create complicated and densely packed integrated circuits with reduced time and effort.

During IC design, cells may be strategically placed according to a floorplan in order to optimize performance of the design. Routing of conductive layers throughout the design may render some of the placed cells operable and functional, while other cells remain as placeholders, or spare cells. Functional cells may be designed to perform the operations of the IC design, while the spare cells may be strategically placed in order to replace cells that fail or, as noted above, in order to facilitate functional ECOs.

Spare cells according to embodiments of the present subject matter may include flexible pin extensions that have routing segments on preferred layers for ECOs. Pins of the spare cells may be contained within a boundary of the cells, and segments of flexible pin extensions may be located outside the boundary of the cells and may be provided on multiple layers. Placement or locations of these segments can be selected based on layer distributions of a critical logic hierarchy of the design, or based on layer distributions of the region surrounding the spare cell and of the overall design. The segments may be created during APR and may include a sufficient number of access points on each layer for later ECO connections. Spare cells, including flexible pin extensions as described herein, provide an efficient and adaptable approach for modifying connections in an ECO. This may reduce the number of mask layer changes made in an ECO and, consequently, the cost of implementing these design changes.

Pins of spare cells including flexible extensions may be routed to PG nets through a top-layer segment of each extension. By routing the spare cells in this manner, later implemented design changes may be enacted with limited reconnection during a functional ECO. Furthermore, strategic layer selection in the spare cells based on layer utilization may ensure that minimal layer changes are needed during functional ECO. Additional advantages of the present subject matter may include easy DRC cleanup, high flexibility for customization, and reduced usage of time and resources because embodiments described herein entail only minor changes in routing resources and no changes to the pin layers. The flexible pin extensions described herein may also be customized and updated for smaller scales, making the present subject matter applicable for future technology generations. Flexible pin extensions are described herein for use with spare cells, however, the flexible pin extensions may also be used with normal standard cells to facilitate ECOs in an efficient manner.

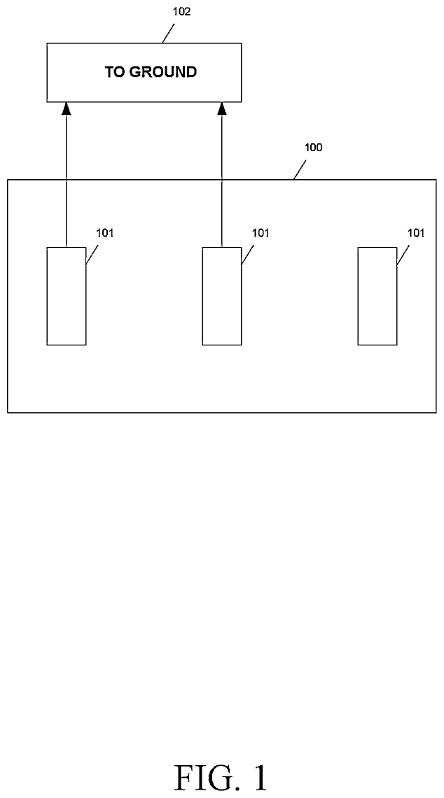

FIG. 1 is a schematic diagram of a spare cell 100 without pin extensions according to an embodiment. Spare cell 100 may include a plurality of pins 101 within the cell boundary. These pins may be connected to PG nets using available routing layers without any constraints. For example, pins 101 may be routed to ground 102 on any layer of the design. This type of spare cell may be used to facilitate a functional ECO, but its utility may be limited when compared to that of a spare cell having flexible pin extensions as described further below.

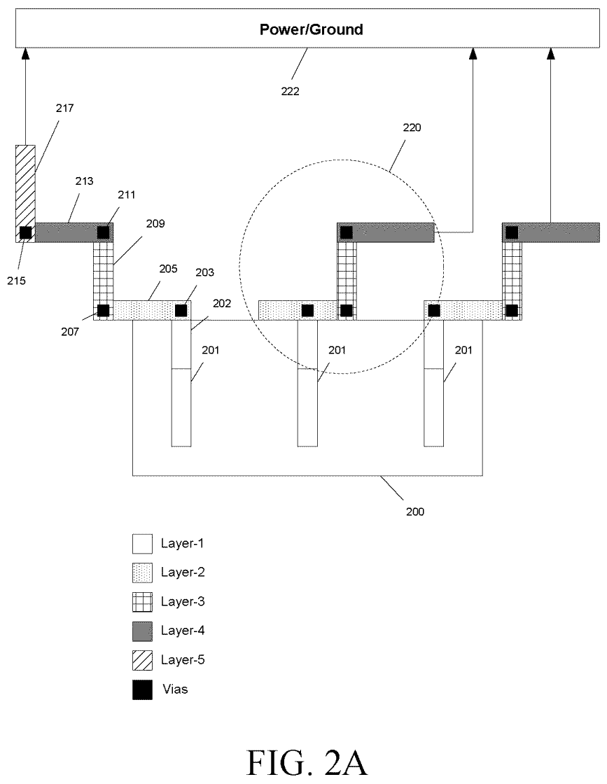

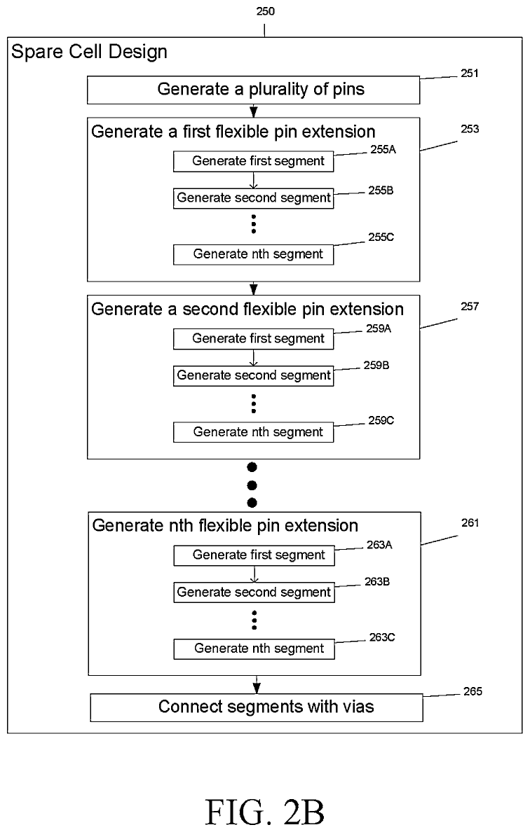

FIG. 2A is a schematic diagram of a spare cell including flexible pin extensions according to an embodiment. Spare cell 200 may include pins 201 that are formed in a first layer, Layer-1, of a layer build-up, and the pins may be connected to a flexible pin extension 220 comprised of a number of segments. Pins 201 may be routed to extend outside of a boundary of the spare cell 200. In an embodiment, a first flexible pin extension segment 202 may extend the pin in the first metal layer outside the boundary of the spare cell. First segment 202 may be integral with pin 201 or may be an additional conductive segment acting as a pin extension. From there, the extended pin structures may be connected to higher level segments of the flexible pin extensions, and the segments may be interconnected by vias.

For example, a first flexible pin extension 220 may further comprise a Layer-2 segment 205, connected to the segment 202 by via 203, a Layer-3 segment 209, connected to Layer-2 segment 205 by via 207, a Layer-4 segment 213, connected to Layer-3 segment 209 by via 211, and a Layer-5 segment 217, connected to Layer-4 segment 213 by via 215. Other flexible pin extensions in the same spare cell may comprise a smaller number of segments and stop at a different metal layer. For example, two of the flexible pin extension shown in FIG. 2 do not include a Layer-5 segment. Alternatively, a flexible pin extension may have more segments that those shown and extend to a greater number of metal layers. For each flexible pin extension, the segment in the uppermost layer may be routed to a PG net 222. As shown in FIG. 2, Layer-5 segment 217 may be routed to a PG net, while in the other flexible pin extensions, this routing occurs at the Layer-4 segment.

The plurality of segments making up a flexible pin extension 220 may define a geometry for the segments corresponding to the shapes and sizes of all segments of the flexible pin extension. The geometry of each flexible pin extension 220 may be selected based on layer a distribution in a region surrounding the extension and in the design as a whole, as well as a logic hierarchy of the dies. Each pin of a spare cell may be assigned extensions independent of other pins in the cell. Additionally, spare cells having similar locations or functions may include flexible pin extensions having similar or the same geometries. In an embodiment, the flexible pin extensions may be selected based on net segment layer distributions. A length of each individual segment may be selected so as to include a sufficient number of access points for later ECO connections. This process will be described in more detail below.

FIG. 2B is a flowchart depicting a method of designing a spare cell according to an embodiment. The spare cell design process 250 begins with generating a plurality of pins at 251. Flexible pin extensions are then generated, beginning with generating a first flexible pin extension at 253. As described above, each flexible pin extension of a spare cell may be connected to a pin of the plurality of pins of the spare cell. Each flexible pin extension may comprise a number of segments, with each segment being generated in a different layer level.

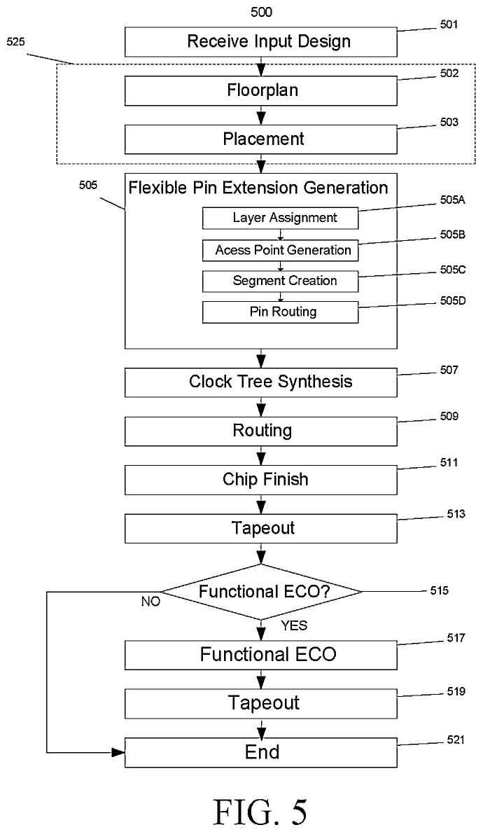

For example, the process of generating first flexible pin extension 253 begins with generating first segment at 255A, the first segment being located in a first level. A second segment located in a second level is then generated at 255B. This process continues for each segment generated until a final “nth” segment, corresponding to an nth layer level of the design is generated at 255C. The process of generating these segments is described in more detail below with respect to FIG. 5.

At 257, a second flexible pin extension may be generated to connect to a second pin. Similar to the generation of the first flexible pin extension described above, a second flexible pin extension may be generated by generating a plurality of segments beginning with a first segment at 259A. A second segment may be generated at 259B, and this process repeats through an nth and final segment at 259C.

In an embodiment, flexible pin extensions may be generated for as many pins as needed from a first flexible pin extension at 255 through an nth flexible pin extension at 261. To generate the nth and final flexible pin extension, a plurality of segments may be generated beginning with a first segment at 263A. A second segment may be generated at 263B, and this process repeats through an nth and final segment at 263C. After all flexible segments have been generated for all flexible pin extensions, the segments may of each flexible pin extension may be interconnected by conductive vias at 265.

While the foregoing describes generating first through “nth” segments for each segment, it is noted that is merely illustrative and, in some embodiments, a flexible pin extension may have only two, or only one segment. Furthermore, the foregoing describes generating first through “nth” flexible pin extensions, but this is also merely illustrative. In some embodiments a spare cell may have any number of pins deemed necessary or warranted according to the design and the designer.

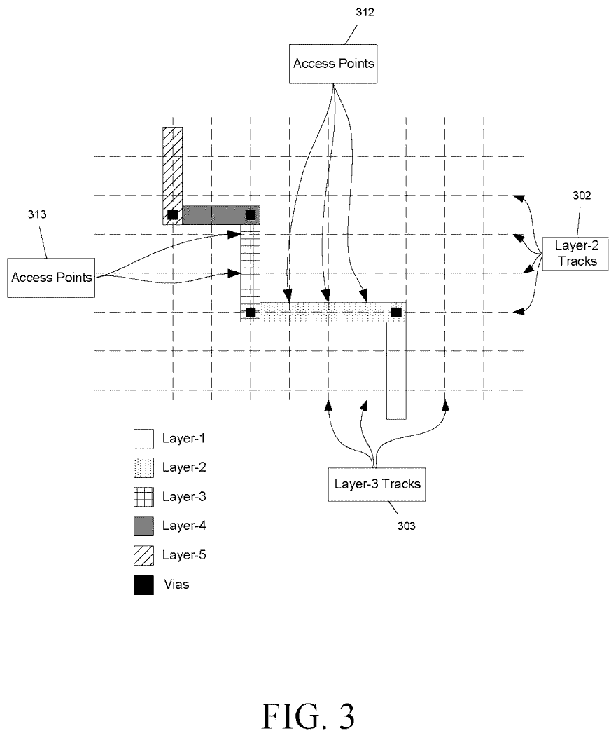

FIG. 3 is a schematic diagram depicting a flexible pin extension according to an embodiment. The flexible pin extension shown in FIG. 3 is similar to that described above and includes segments in each layer from Layer-1 through Layer-5. The grid depicted by dashed lines in FIG. 3 represent layer tracks that define positions where conductive material for that layer may be placed. For example, Layer-2 302 tracks may run horizontally through the design, with adjacent tracks being spaced apart by a fixed pitch. Layer-3 tracks 303 may run vertically through the design and may be spaced apart by a second pitch. Intersections between segments and tracks of adjacent layers define access points for ECO connections to segments of the flexible pin extensions. While FIG. 3 shows tracks only in a grid pattern, the present subject matter is not so limited, and tracks may be provided in any functional geometry that a designer sees fit.

The tracks may provide a means for connecting a segment of the flexible pin extension to routing in adjacent layers. These connections may be made through vias that interface with access points of the segments. For example, the Layer-2 segment according to an embodiment depicted in FIG. 3 has three access points 312, one at each position where the segment intersects with a Layer-3 track. The Layer-3 segment according to the embodiment has two access points 313 where the segment and a Layer-2 track intersect. The access points 312 and 313 represent locations on the segments where connection may be made to an adjacent layer during ECO. The number of access points on each segment may be determined by the design layout.

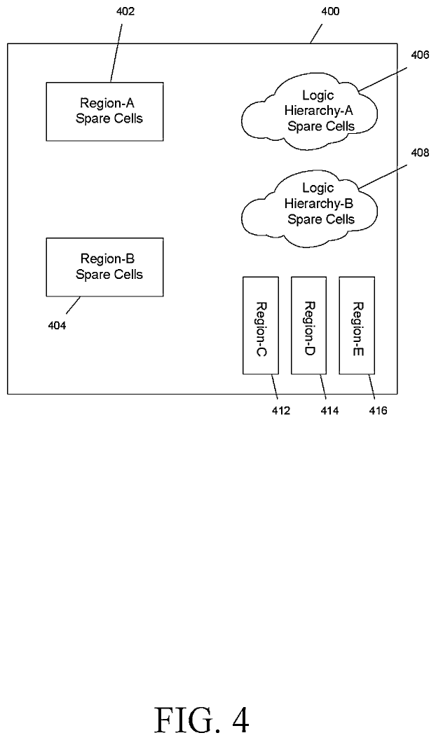

FIG. 4 is a plan diagram of a design layout 400 according to an embodiment. Within the overall design layout 400 a plurality of different regions may be defined. For example, design layout 400 may comprise a first region, Region-A 402, having spare cells therein and a second region, Region-B 404, having spare cells therein. The design layout 400 may further include additional regions such as regions 410, 412, and 414. The design may also contain a set of logic hierarchies 406 and 408. Spare cells may be provided that are designated for logic hierarchies within the layout. In an embodiment, logic hierarchy-A 406 and logic hierarchy-B 406 may include critical logic paths and spare cells including flexible pin extensions may be provided for each hierarchy.

Region-A 402 and Region-B 404 may include input/output (I/O) connections for carrying signals into and out of the region. The spare cells in these regions may include segments on various layers. When an ECO is implemented that calls for I/O connections to a spare cell, the layers on which these I/O connections are made are selected based on the net segment layer distribution. For example, an ECO may call for one or more spare cells in region 402 to include new I/O connections. In such an embodiment, the layer in which these connections are made may be selected based on the net segment layer distribution of region 402. Similarly, an ECO may call for I/O connections to region 404, and the layers for these connections may be selected based on the net segment layer distribution of region 404.

Another example ECO may call for I/O connections to a spare cell associated with logic hierarchy-A 406 or logic hierarchy-B 408. For such an ECO, the layers in which these connections are made may be selected based on layer distributions within the logic hierarchies. By assigning layers for I/O connections based on the specific layer utilization of the affected hierarchy, the number of layer changes for the ECO may be minimized and efficiency of the ECO may be increased.

FIG. 5 is a flowchart 500 depicting a design method including a functional ECO according to an embodiment. The method may begin by receiving a circuit design at 501. A floorplanning operation 502 then generates a floorplan which comprises a preliminary layout of the design, including approximate sizes and locations for different functional blocks and components. The floorplan stage creates a blueprint for subsequent operations such as placement and routing.

After floorplanning, the method proceeds to a placement operation 503 in which the position of each component in the design may be determined based on the floorplan. In an embodiment, an APR tool may receive the IC design of the floorplan and generate a design layout with optimized positions for a plurality of spare cells and a plurality of functional cells. The placement stage 503 may include optimizing the design and balancing competing problems including, but not limited to, wire length, performance, power consumption, and size. Together, the floorplan stage 502 and the placement stage 503 may make up a design layout generation phase 525. In this phase, a design layout may be generated from the input design through the floorplan and placement processes.

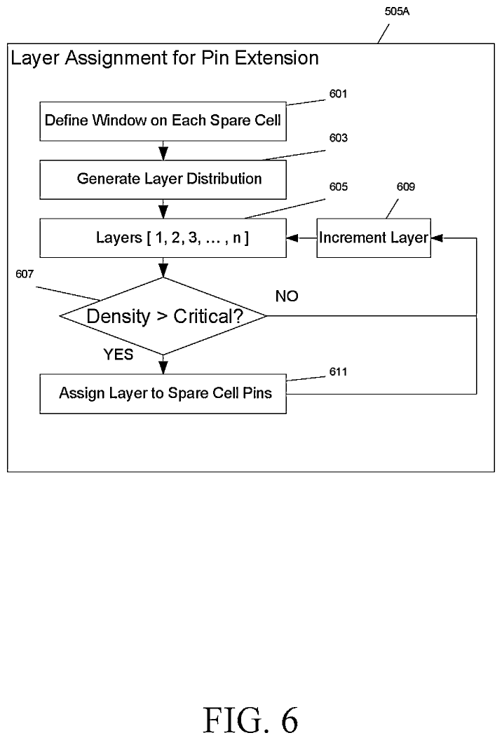

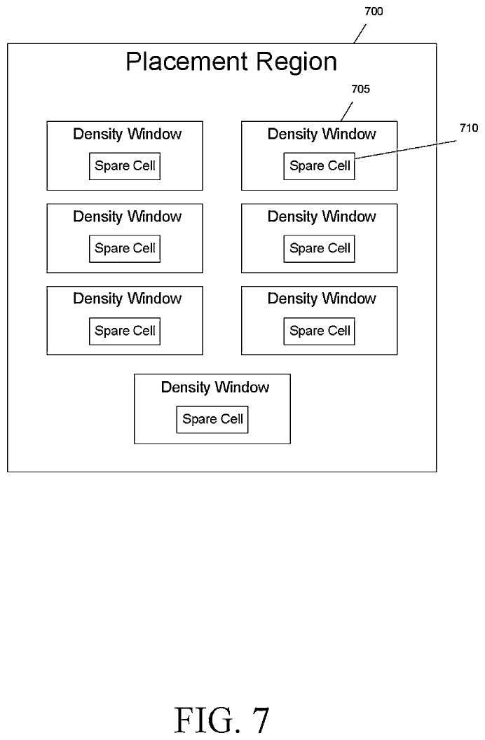

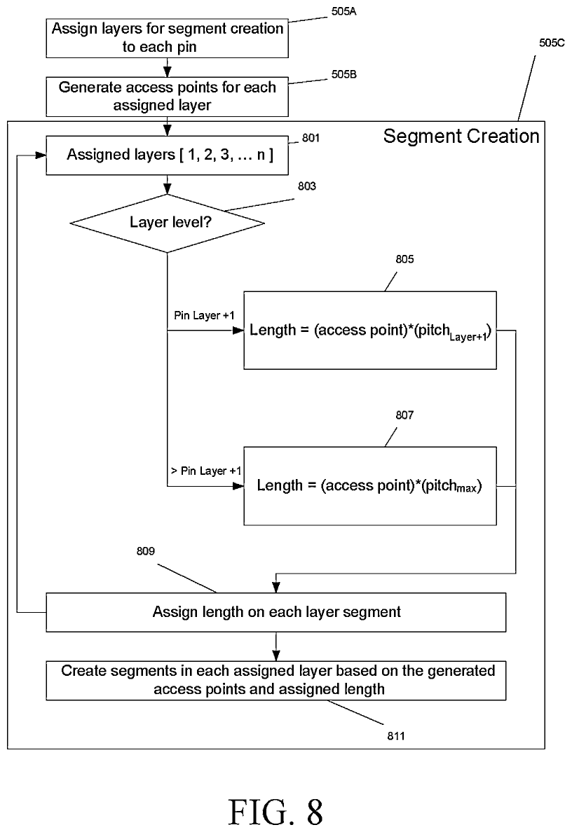

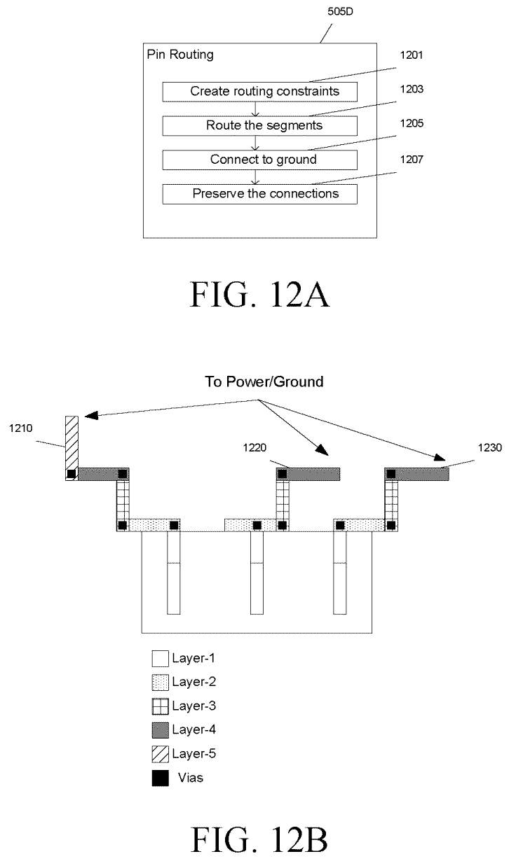

After placement, the method may proceed to a flexible pin extension flow 505 in which the flexible pin extensions are created. Flexible pin extension flow 505 comprises operations 505A-505D and begins with a layer assignment stage 505A. During layer assignment, a determination is made as to which layers of the layer build-up may be designated for placement of flexible pin extension segments. This process is described in more detail below with reference to FIG. 6 and FIG. 7. After layer assignment, access points are generated in 505B and segments are created in 505C. These processes are described in more detail below with reference to FIGS. 8-11. After creation of the segments a pin routing process occurs in 505D. This process is described in more detail below with reference to FIG. 12.

Following the flexible pin extension flow 505, the method proceeds to clock tree synthesis in 507. This process may balance clock delay for all clock inputs such that a clock signal is evenly distributed to all sequential elements throughout the design. Clock tree synthesis 507 may comprise inserting buffers and inverters at particular locations within the design to ensure proper timing.

After clock tree synthesis 507, routing 509 is performed for the design. This process involves interconnecting components and devices within the integrated circuit. In routing 509, a network of conductive wiring is created to form connections between functional cells of the IC design. Spare cells with flexible pin extension may be left out of this initial routing process. This may allow the spare cells to remain available for later use, for example in routing to implement a functional ECO. Routing process 509 may output a routed design that is ready for fabrication during tapeout.

After routing, chip design may be complete, as indicated at 511. Following chip finish, the design is ready for tapeout 513. During tapeout, the design may be processed and fabricated. This is generally the final stage for an integrated circuit device; however, the design may need to be altered by an ECO. At 515, the method continues, and it is determined whether or not a functional ECO is needed.

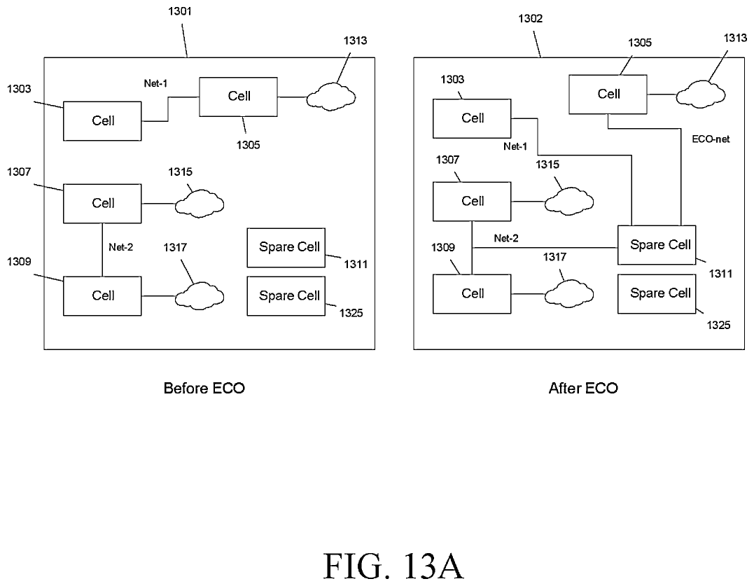

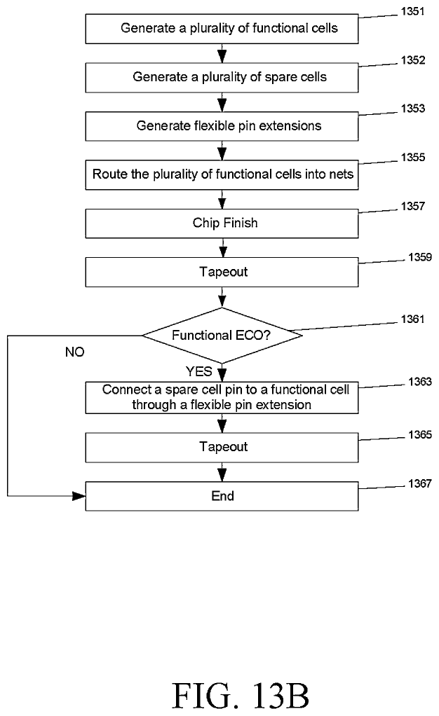

Functional ECOs may be desired for many reasons, including as a response to design errors, to implement new features, or to improve performance. If it is determined that an ECO is not advantageous, the method proceeds to end at 521. If it is determined in 515 that a functional ECO is advantageous, that ECO may be implemented at 517. This process may use spare cells and the flexible pin extensions to more easily implement the desired changes. This will be described in more detail below in reference to FIGS. 13-16. After implementing the functional ECO, the method may proceed to tapeout at 519 where the updated design is processed and fabricated. After the updated design is taped out, the process may end at 521. However, other embodiments may call for additional ECOs, and the process may return to 515, repeating the implementation processes as needed.

FIG. 6 is a flowchart depicting a layer assignment phase 505A of a design method according to an embodiment. In an embodiment, a window may first be defined around each spare cell at 601. The dimensions of the windows may be a default setting from the design, tool and may be based on a conductive layer density, or congestion, in the region. Alternatively, the window may comprise a user defined x-dimension and y-dimension. For example, the user may calculate these dimensions based on a percentage of a max load value, stored in a .lib file, for an output pin of the spare cell. In an embodiment, the x-dimension may be a horizontal dimension and it may be set to equal to a ratio of the percentage of the max load to an average horizontal resistance and capacitance. The y-dimension may be a vertical dimension and may be set to equal a desired ratio of the percentage of the max load to an average horizontal resistance and capacitance. In another embodiment, the user may instead use a set distance to define the dimensions of the window.

After windows are defined, the method proceeds to 603 in which layer distributions are generated for the layers of each spare cell. As depicted in 605, layer distribution generation may iterate through each layer of a design layout. A first layer level may be defined as Layer-1 and the layer directly above Layer-1 may be defined as Layer-2. For a design layout having n number of layers, a layer distribution is generated for n layers, from Layer-1 through Layer-n. These distributions are used in calculations to determine whether to assign a layer to particular pins.

For each layer, a density of the layer distribution within the defined window may be compared against a critical density, as shown in 607. The critical density may be a user-defined value based on a design layer distribution map. For example, the critical density may be defined as the window being 30% occupied by conductive material, or 40% occupied, or any other amount defined by a user based on the layout and constraints of the desired design. A layer density being greater than the critical density indicates a sufficiently large amount of routing on that layer such that flexible pin segments should be applied on the layer.

In an embodiment, the determination in 607 is first made with respect to Layer-1. If it is determined that the density in the defined window is not greater than a critical density for this layer, the method proceeds to 609 and increments to Layer-2. The method may then proceed back to 607 and a determination is made for Layer-2. If, instead, the comparison in 607 determines that the density in Layer-1 is greater than the critical density, Layer-1 is assigned to pins of the spare cell. This assignment may be made to all pins, or only to some, based on relevant layer distributions. After assignment of the layer, the method again proceeds to 609 and increments to the next layer. This continues until it is performed for each layer of a design.

FIG. 7 is a plan diagram depicting an arrangement of spare cells 710 according to an embodiment. The figure shows how spare cells 710 may be arranged within a particular placement region 700. In an embodiment, placement region 700 may be a region in an overall design layout similar to Regions A-D as described above with respect to FIG. 4. A plurality of spare cells 710 may be arranged within the region 700. During the layer assignment phase, a density window 705 may be defined around each spare cell of the plurality of spare cells. For each layer, the density within a window 705 is compared against a critical density, and if the density is greater than the critical density, the layer is assigned to the corresponding spare cell within the window. After layer assignment, the method proceeds to access point generation as described above with reference to FIG. 5 and described in more detail below.

FIG. 8 is a flowchart depicting access point generation 505B and segment creation phases 505C of the design method according to an embodiment. Following layer assignment, at 505B, a number of access points may be generated for segments on each assigned layer. The number of access points generated for each assigned layer may be greater than or equal to one, and the number may be determined based on layer distributions in the defined window. In some embodiments, a Layer-1 segment extends pins outside of the cell boundary. These Layer-1 segments may be assigned one access point for connection to another segment of a flexible pin extension. For successive segments, the number of access points may be determined based on the design and layer distributions. After access points are generated, the method may proceed to 505C and the segments of a flexible pin may be created.

During the segment creation phase 505C, the process iterates through each assigned layer and creates a segment of a specific length determined by the number of access points generated in 505B and pitches of adjacent layer tracks. In an embodiment, for a Layer-1 segment, the segment length may be predetermined in order to extend a pin outside of a cell boundary such that one access point on the first segment is available for connection to layers above.

For segments in higher layer levels, the process may begin by determining what layer is at issue, as shown at 803. For a layer immediately above a pin layer, the segment creation process proceeds to 805. For this layer, the length of a segment may be defined as the number of access points multiplied by a pitch of tracks for a layer immediately above the layer in question. For example, if pins are formed in a Layer-1 level, segments created in Layer-2 would proceed according to 805, and the relevant pitch would be the pitch of Layer-3 tracks. After calculating lengths for this layer, the method may proceed to 809 and the lengths may be assigned to the layer segments.

For other layers, the segment creation process proceeds to 807. For these layers, the length of a segment may be defined as the number of access points multiplied by the greater of a pitch of tracks for a layer below the segment to be created and a pitch of tracks for a layer above the segment to be created. This pitch may be defined as pitchmax. For example, in creating a segment in Layer-4, the pitch of Layer-3 tracks may be compared to the pitch of Layer-5 tracks. The greater of these two pitches may be defined pitchmax and multiplied by the number of access points to generate a segment length. After calculating this length, the method proceeds to 809 and this length may be assigned to the layer segment. After assigning a length, the process may return to 801 and move on to the next assigned layer.

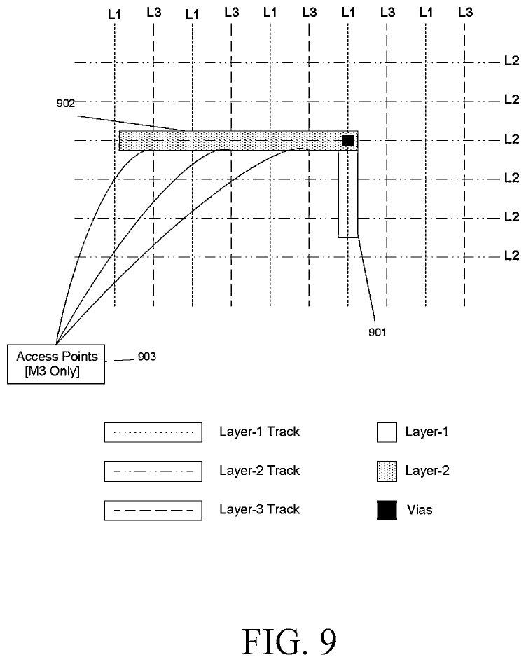

FIG. 9 is a schematic diagram depicting segments of a flexible pin extension according to an embodiment. A Layer-2 segment 902 may be created through a segment creation operation as described above with reference to FIG. 8. In an embodiment, Layer-1 tracks L1 and Layer-3 tracks L3 may run in a first direction through the design, while Layer-2 tracks L2 run in a second direction that is perpendicular to the first direction. A segment 901 of a spare cell may be formed in the Layer-1 level and may extend along a track L1 in the second direction. Segment 901 may be a pin of a spare cell or may be Layer-1 segment of a flexible pin extension that is connected a pin of a spare cell.

Segment 902 may be formed to overlap the Layer-1 structure, and may extend in the second direction along a track L2. Segment 902 may be connected to pin 901 through a conductive via. The processes described above with reference to FIGS. 6 and 8 may be used to create segment 902. In an embodiment 901 may be a spare cell pin that is assigned a Layer-2 segment in the layer assignment stage. Then, a number of access points may be generated for the segment during access point generation. For example, the layer density in the window defined around the spare cell of pin 901 may determine that segment 902 should have three access points.

The segment creation process may then translate this into a proper length for the segment. Because the Layer-2 layer is the layer directly above the pin layer, the length of segment 902 is determined by the equation set forth at 805 of FIG. 8 as described above. The number of access points may be set as three, and the relevant pitch is the pitch of the tracks L3. After determining the appropriate length, segment 902 may be created. As shown in FIG. 9, segment 902 includes three access points 903. Because segment 902 is in the Layer-2 level and pins are located in the Layer-1 level, access points for segment 902 may be generated along intersections with tracks L3 in the Layer-3. However, as described in more detail below, for higher layer segments, access points may be generated for connection to tracks both above and below the layer level of a particular segment.

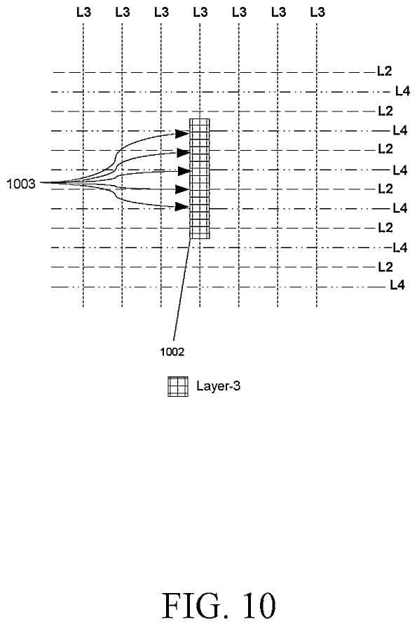

FIG. 10 is a schematic diagram depicting a segment of a flexible pin extension according to an embodiment. Segment 1002 may be in the Layer-3 level and may extend along a track L3. Because the segment is not in Layer-2, the process of creating this segment may proceed according to the equation set forth in 807 of FIG. 8, wherein the number of assigned access points is multiplied by the greater of the pitch of L2 below and the pitch of L4 above. This may generate a number of access points 1003 for the segment that allow for connection from conductive layers below in the Layer-2 level and conductive layers above in the Layer-4 level. This provides for increased flexibility of routing in response to a functional ECO. Each successive segment of an example flexible pin extension may include access points to connect to routing in higher and lower tracks.

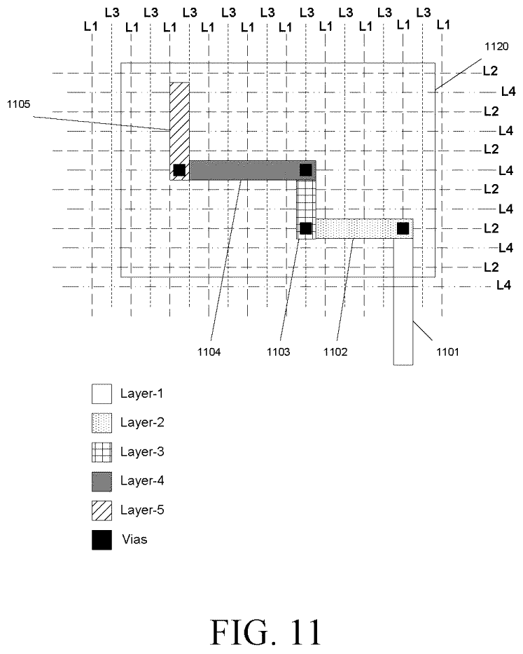

FIG. 11 is a schematic diagram depicting segments of a flexible pin extension 1120 according to an embodiment. The flexible pin extension may connect to a pin 1101 of a spare cell of an integrated circuit design. Pin 1101 may extend outside of a cell boundary or may be contained within a cell boundary and connect to a first segment that extends the pin outside of the cell boundary. Flexible pin extension 1120 may comprise a Layer-2 segment 1102 that extends along a track L2. The Layer-2 segment 1102 may include access points for connection to routing in the Layer-3 level. Segment 1102 may be connected to a Layer-3 segment 1103 that extends along a track L3. The Layer-3 segment 1103 may include access points for connection to routing both in the Layer-2 level below and in the Layer-4 level above. Segment 1103 may be connected to a Layer-4 segment 1104 that extends along a track L4. The Layer-4 segment 1104 may include access points for connection to routing both in the Layer-3 level below and the Layer-5 level above. Segment 1104 may be connected to a Layer-5 segment 1105 that extends along a Layer-5 track (not shown). If Layer-5 is a top layer of the design, segment 1105 may include access points for connection to routing in the Layer-4 level below. If, however, the design includes routing in a Layer-6 level above, the Layer-5 segment 1105 may also include access points for connecting to routing in the Layer-6 level. After the segments are created, the method proceeds to pin routing, as shown in 505D of FIG. 5.

FIGS. 12A-12B are a flowchart depicting a pin routing phase of the design method and a schematic diagram of a spare cell according to an embodiment. FIG. 12A shows the pin routing process 505D in greater detail. Following creation of the segments, routing constraints are created at 1201. The constraints may be design rules that impose certain limitations on wiring geometries and spacing in order to ensure that the design meets performance and reliability standards. As non-limiting examples, the constraints of 1201 may comprise a minimum spacing rule that protects against shorts by ensuring a minimum distance between interconnects and a maximum wire length rule that protects against timing delays. The routing constraints may comprise any other design rule or constraint implemented to increase overall performance. In an embodiment, the routing constraints may be the segments of the flexible pin extensions and their minimum segment lengths, and the power-ground connection layers that connect flexible pin extensions to a PG net.

With these constraints in place, the segments of the flexible pin extensions may be routed at 1203. This process may be performed by an APR tool, for example using the same tool used previously for initial placement routing of the rest of the IC design. After routing, the pins may be connected to ground (or a reference voltage) at 1205. The pin routing may be implemented such that only the upper-most segment of a flexible pin extension is routed to a PG net. These connections may then be preserved at 1207 because tying the pins of the spare cells to a PG net may decrease noise in the circuit. The pins remain tied to a PG net unless a functional ECO is implemented that calls for re-routing the spare cell to be included as part of the functional design.

FIG. 12B is a schematic diagram depicting routing of flexible pin extensions to a PG net. Each flexible pin extension may be connected to a PG net, with this connection provided only from a top layer segment. For example, in a flexible pin extension having a Layer-5 segment 1210, the connection may occur by routing segment 1210 to a PG net. For other flexible pin extensions wherein the upper-most segment is located in Layer-4, the connections may occur by routing Layer-4 segments, 1220 and 1230, to a PG net. Routing of these segments to a PG net may minimize the number of reconnections used to implement a functional ECO.

FIG. 13A shows plan diagrams depicting design layouts before and after an ECO according to an embodiment. Layout 1301 represents a design before ECO, and may comprise a plurality of cells, including both functional and spare cells, and a plurality of circuit elements. The circuit elements may represent any number of design components including connections to logic hierarchies in the layout, or external connections to and from the cells. In an embodiment, the layout before an ECO may comprise a first net, Net-1, and a second net, Net-2. The first net may comprise a first cell 1303, a second cell 1305, and a first circuit element 1313. The second net may comprise a third cell 1306, a fourth cell 1309, a second circuit element 1315, and a third circuit element 1317. In a pre-ECO state of Net-2, third cell 1307 may be connected to both second circuit element 1315 and fourth cell 1309. Fourth cell 1309 may further connect to third circuit element 1317.

Layout 1301 may further comprise a plurality of spare cells including a first spare cell 1311 and a second spare cell 1325. Both spare cells 1311 and 1325 may include flexible pin extensions to facilitate implementation of ECOs. In an embodiment, spare cells 1311 and 1325 both comprise an AND gate. Geometries of flexible pin extensions for each spare cell may be individually created by the process described above, however due to similarities in location within the design and function of the spare cell, a geometry of flexible pin extensions of spare cell 1311 may have a same pattern as a geometry of flexible pin extensions of spare cell 1325. Before an ECO is implemented, spare cells 1311 and 1325 may be isolated from functional cells and elements of the design.

Layout 1302 depicts the design after implementing a functional ECO. In an embodiment, an example ECO calls for Net-1 and Net-2 to be logically ANDed together, and calls for that the output of this operation be connected to an input of second cell 1305. Based on these conditions, the ECO may call for re-routing connections through spare cell 1311 which comprises an AND gate. For example, the connection between cell 1303 and cell 1305 may be broken and Net-1 may be connected to an input of spare cell 1311. Additionally, Net-2 may be connected to an input of spare cell 1311. An output of the spare cell 1311 may be connected to cell 1305 to create a new ECO-net, and completing the instructions of the ECO. Spare cell 1325 may remain isolated and available for incorporation in later ECOs, if needed. By incorporating flexible pin extensions into spare cell 1311, the number of changes involved in implementing the ECO may be reduced.

FIG. 13B is a flowchart depicting a method designing a layout according to an embodiment. The process in FIG. 13B is an implementation of the process shown and described with reference to FIG. 5 for layouts as shown and described with respect to FIG. 13A. The process may begin by generating a plurality of functional cells at 1351 and generating a plurality of spare cells at 1352. In some embodiments, the generation of these cells may take place simultaneously, while in other embodiments the cells are generated in successive steps. The generation of the functional and spare cells may comprise a floorplanning operation and a placement operation.

After generating the cells, flexible pin extensions are generated at 1353 to connect to pins of the spare of the spare cells. In an embodiment at least one flexible pin extension is generated to connect to a first pin of a first spare cell of the plurality of spare cells. A routing may be performed at 1355 to connect the functional cells into nets. As described above with respect to FIG. 13A, at this stage the spare cells and flexible pin extensions may remain isolated from functional cells in the layout.

After routing, the chip may be finished as indicated at 1357. The design may then proceed to tapeout and may be processed and fabricated. It may be later determined, however, that a functional ECO is needed to fix an error or to improve design. This determination is made at 1361.

If an ECO would not be advantageous, the process may proceed to 1367 and end. But, an ECO would be advantageous, the process may proceed to 1363 where new connections are made. As described in FIG. 13A above, an example ECO may call for a net comprising functional cells to be routed through a spare cell. To accomplish this, the spare cell may be connected to a functional cell through a flexible pin extension at 1363. After implementing the ECO, the method may proceed to tapeout at 1365 where it is processed and fabricated. After tapeout, the process may end at 1367.

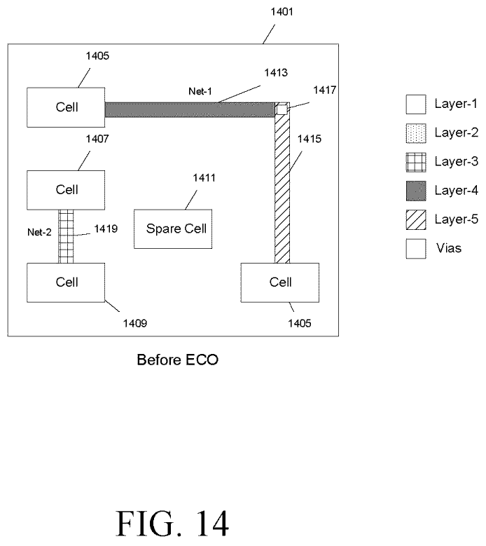

FIG. 14 is a schematic diagram of a design layout 1410 including conductive layers according to an embodiment. Layout 1410 shows the state of a design before ECO. The structures making up layout 1410 may be the same as those described above with respect to the pre-ECO layout in FIG. 13. In an embodiment, a first cell 1403 and a second cell 1405 may be connected as part of a first net, Net-1. This connection may be made through a series of conductive layers. For example, cell 1405 may be connected to a first conductive layer 1413 in Layer-4. The first conductive layer 1413 may connect to a via 1417 that connects to a second conductive layer 1415 located in the Layer-5 layer. The second conductive layer 1415 may in turn be connected to the second cell 1405. A second net, Net-2 may include a third cell 1407 connected to a fourth cell 1409. This connection may be made through a Layer-3 conductive layer 1419.

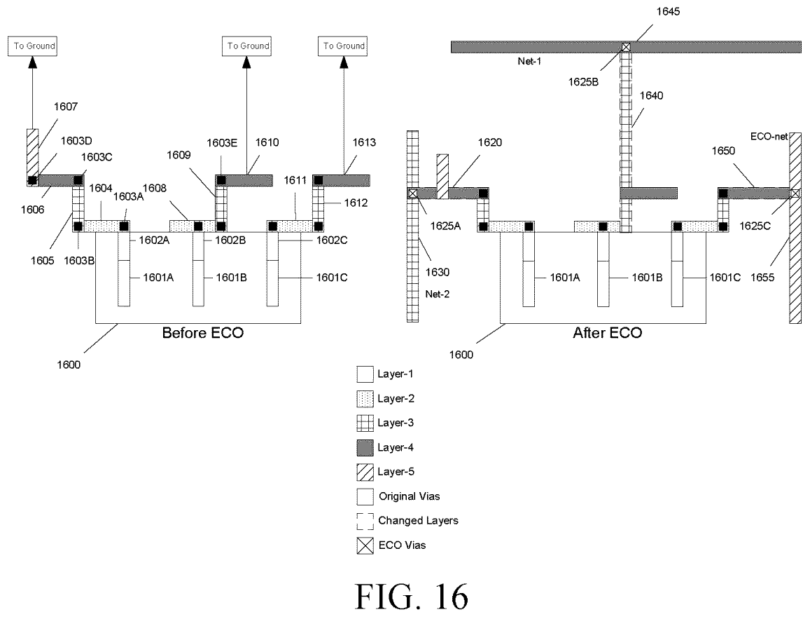

By equipping a spare cell 1411 of the layout with flexible pin extensions having segments on various layers, conductive layers 1413, 1415, and/or 1419 can be easily connected to segments of the spare cell 1411 in corresponding or adjacent layers during ECO, thereby minimizing the number of layer changes enacted. For example, in the ECO calling for Net-1 and Net-2 to connect as inputs to spare cell 1411, the Layer-4 conductive layer 1413 may use just one Layer-3 route to connect to a layer of a flexible pin segment, and the Layer-3 conductive layer 1419 may use just one Layer-4 route to connect a segment of the flexible pin extension of spare cell 1411. Similarly, if the ECO calls for the output of this operation to be an input to cell 1405, a Layer-3 segment of the flexible pin extension of spare cell 1411 may connect to the Layer-5 conductive layer 1415 using just one Layer-4 route. This routing scheme will be described in more detail below with reference to FIG. 16.

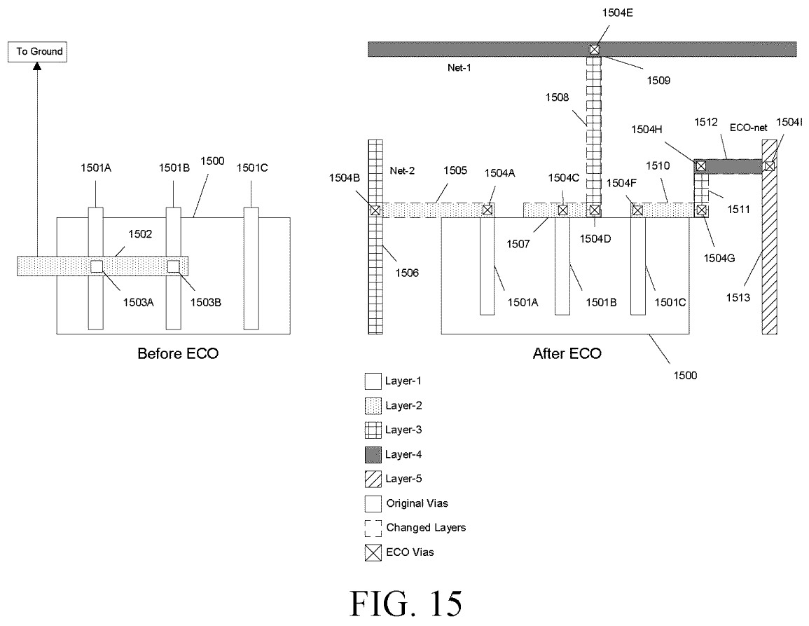

FIGS. 15 and 16 demonstrate how flexible pin extensions may reduce a number of layer changes involved in implementing an ECO. FIG. 15 is a schematic diagram of a spare cell 1500 without flexible pin extensions before and after an ECO according to an embodiment. FIG. 16 is a schematic diagram of a spare cell 1600 having flexible pin extensions before and after the same ECO according to an embodiment.

As shown in FIG. 15, a pre-ECO cell 1500 may include pins 1501A, 1501B, and 1501C. In an embodiment, these pins may extend beyond an edge of the cell boundary. In other cases, pins may be formed wholly within the cell boundary and extended by a pin extension, or pre-ECO pins may not extend beyond the cell boundary at all. Pins 1501A and 1501B may be routed to a PG net through a Layer-2 conductive layer 1502. Pin 1501A may connect to conductive layer 1502 through a first via 1503A, and pin 1501B may connect to conductive layer 1502 through a second via 1503B. The layout depicted after ECO shows all layer changes that need to be made in order to implement an example ECO.

The example ECO depicted herein may be the same as change described above with reference to FIGS. 13-14. This ECO calls for the spare cell to be an AND gate combining a first net, Net-1, and a second net Net-2, and for an output of the spare cell AND gate to connect another cell, creating an ECO-net. To generate an input from Net-1, the spare cell may need to connect to a conductive layer in the Layer-4 level. To generate an input from Net-2, the spare cell may need to connect to a conductive layer in the Layer-3 level. To connect an output and create the ECO-net, the spare cell may need to connect to a conductive layer in the Layer-5 level.

After the ECO is implemented, first pin 1501A may be electrically connected to a Layer-3 conductive layer 1506 to form the Net-2 input to the spare cell. To implement this change and comply with spacing requirements and routing constraints, original layer 1502 and original vias 1503A and 1503B may be replaced in the design. Instead, a new Layer-2 segment 1505 may be called for to provide a route between layer 1506 and pin 1501A. Additionally, new ECO vias 1504A and 1504B may be called for to provide connection between layers on adjacent layer levels. As such, this ECO enacts changes in Layer-2, as well as a first via layer (Via-1, between Layer-1 and Layer-2), and a second via layer (Via-2, between Layer-2 and Layer-3).

After the ECO is implemented, second pin 1501B may be electrically connected to a Layer-4 conductive layer 1509 to form the Net-1 input to the spare cell. To implement this change, a new Layer-2 conductive layer 1507 may be inserted to connect to pin 1501B. A Layer-3 conductive layer 1508 may also be inserted as an intermediate layer to make connection to the Layer-4 conductive layer 1509. Additionally, ECO vias 1504C. 1504D, and 150E may be called for to make the necessary inter-layer connections. As such, this ECO implements changes in Layer-2 and Layer-3, as well as in the Via-1 layer, Via-2 layer, and a Via-3 layer (between Layer-3 and Layer-4).

After the ECO is implemented, third pin 1501C may be electrically connected to a Layer-5 conductive layer 1513 to form the output of the spare cell and the Eco-net. To implement this change, a Layer-2 conductive layer 1510 may be connected to pin 1501C, and intermediate conductive layers 1511 and 1512 may be formed in Layer-3 and Layer-4, respectively. Additionally, ECO vias 1504F, 1504G, 1504H, and 1504I may be called for to make the necessary inter-layer connections. As such, this ECO implements changes in Layer-2, Layer-3, and Layer-4, as well as in the Via-1 layer, Via-2 layer, Via-3 layer, and a Via-4 layer (between Layer-4 and Layer-5).

Taken together, the example ECO may require seven total layer changes and fifteen individual corrections. As will be described below with respect to FIG. 16, by using a spare cell equipped with flexible pin segments, the number of total changes and total layer changes may be reduced, leading to more efficient design changes.

Before implementation of an example ECO, spare cell 1600 may comprise a first pin 1601A, a second pin 1601B, and a third pin 1601C. First pin 1601A may be connected to a Layer-1 segment 1602 that extends the pin outside of the cell boundary. Segment 1602A may be connected to a Layer-2 segment 1604 by a first via 1603A. Layer-2 segment 1604 may be connected to a Layer-3 segment 1605 by a second via 1603B. Layer-3 segment 1605 may be connected to a Layer-4 segment 1606 by a third via 1603. Layer-4 segment may be connected to a Layer-5 segment 1607 by a fourth via 1603D. Layer-5 segment, as a top layer segment, may be connected to ground.

The pre-ECO layout depicted in FIG. 16 further shows connections for the second pin 1601B and third pin 1601C. For purposes of clarity and brevity, not every via in these connections is explicitly labeled, however it is noted that connections between segments on adjacent levels are made by conductive vias similar to those having explicit reference numbers.

Before an ECO, second pin 1601B may be connected to a Layer-1 segment 1602B. Layer-1 segment 1602B may be connected to a Layer-2 segment 1608 by a via. Layer-2 segment 1608 may be connected to a Layer-3 segment 1609 by another via. Layer-3 segment 1609 may be connected to a Layer-4 segment 1610 through an additional via. Layer-4 segment 1610, as a top layer segment, may be connected to ground. Third pin 1601C may be connected to a Layer-1 segment 1602C that extends outside of the cell boundary. Layer-1 segment 1602C may be connected to a Layer-2 segment 1611 by a via. Layer-2 segment 1611 may be connected to a Layer-3 segment 1612 by another via. Layer-3 segment 1612 may be connected to a Layer-4 segment 1613 by an additional via. Layer-4 segment 1613, as a top layer segment, may be connected to ground.

The example ECO depicted herein may be the same change as described above with reference to FIGS. 13-15. This ECO calls for the spare cell to be an AND gate combining a first net. Net-1, and a second net Net-2, and for an output of the spare cell AND gate to connect another cell, creating an ECO-net. To generate an input from Net-1, the spare cell may need to connect to a conductive layer 1645 in the Layer-4 level. To generate an input from Net-2, the spare cell may need to connect to a conductive layer 1630 in the Layer-3 level. To connect an output to another cell and create the ECO-net, the spare cell may need to connect to a conductive layer 1655 in the Layer-5 level. Some structures that are unchanged by the ECO are not labeled in the after ECO depiction of spare cell 1600, however, it is noted that these structures are the same as those described above with respect to the configuration before the ECO.

After implementing the ECO, pin 1601A may be electrically connected to Layer-3 conductive layer 1630 such that Net-2 is input into the spare cell. To form this connection while maintaining spacing and routing constraints may call for a new Layer-4 segment 1620 to extend outwards along a Layer-4 track and intersect with 1630. A new ECO-via 1625A may also be inserted in order to electrically connect 1630 to the new segment 1620. Additionally, this change may call for removal of original via 1603D to break the connection between the pin and ground. As such, making this connection only implements changes in the Layer-4 level and in the Via-3 and Via-4 levels.

After implementing the ECO, pin 1601B may be electrically connected to Layer-4 conductive layer 1645 such that Net-2 is input into the spare cell. To form this connection, a new segment 1640 may be called for that extends outwards along a Layer-3 track and intersects with 1645. A new ECO-via 1625B may also be inserted in order to electrically connect 1645 to the new segment 1640. Additionally, this change may call for removal of original via 1603E to break the connection between the pin and ground. As such, implementing this connection only calls for changes in Layer-3 and in Via-3.

After implementing the ECO, pin 1601C may be electrically connected to Layer-5 conductive layer 1655 as an output of the spare cell and to form an ECO-net. To form this connection, a new segment 1650 may be called for that extends outwards along a Layer-4 track to intersect with layer 1655. A new ECO-via 1625C may also be inserted in order to electrically connect 1655 to the new segment 1650. Because 1650 replaces original segment 1613, no additional change is needed to break connection between the pin and ground. As such, implementing this connection only calls for changes in Layer-4 and in Via-4.

Taken together, implementing the ECO in a design comprising spare cells having flexible pin extensions may call for only four total layer changes (three less than compared to designs having spare cells without flexible pin extensions) and only eight individual changes (seven less than compared to designs having spare cells without flexible pin extensions). This may increase the efficiency of implementing a functional ECO and may decrease associated costs and process times. While the foregoing embodiments describe an ECO that provides connection to all pins of a spare cell, this is not always the case. In other embodiments, as described in more detail below, an ECO may call for connection to one pin of a spare cell while another pin of that spare cell remains routed to a PG net.

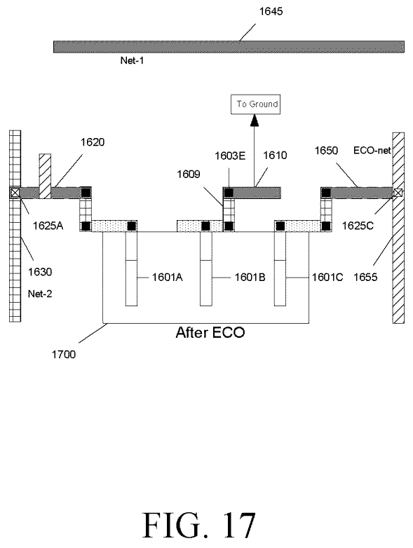

FIG. 17 is a schematic diagram of a spare cell 1700 after an ECO according to an embodiment. Structures and components in the layout depicted in FIG. 17 may be the same as those described above with reference to FIGS. 13-16, however, the ECO of this embodiment may not call for Net-1 to be connected to the spare cell. In one example, spare cell 1700 may comprise a NOR gate rather than an AND gate, and the ECO may call for the output of Net-2 to be inverted. As such, the ECO only needs one pin of the spare cell to receive an input and one pin to pass along an output.

In an embodiment, first pin 1601A may be electrically connected to receive the Net-2 input after the ECO. To make this connection, the same changes as described above with respect to FIG. 16 may be implemented such that pin 1601A is connected to Layer-3 conductive layer 1630 through a flexible pin extension. After the ECO, third pin 1601C may be electrically connected to Layer-5 conductive layer 1655 to output a signal from the spare cell and create an ECO-net. To make this connection, the same changes as described above with respect to FIG. 16 may be implemented such that pin 1601C is connected to the Layer-5 conductive layer 1655 through a flexible pin extension. Because the ECO does not call for any additional inputs or outputs for cell 1700, second pin 1601B may remain in the same state as before the ECO, including the connection to ground.

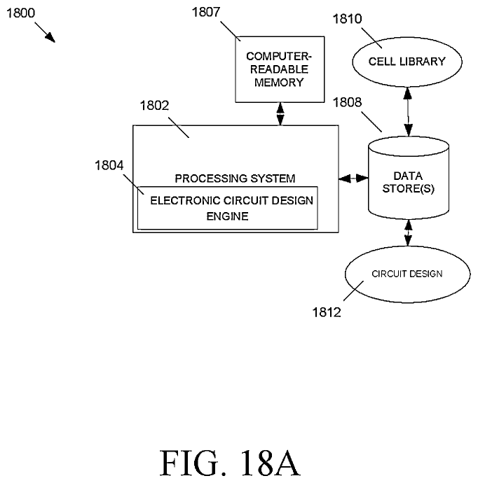

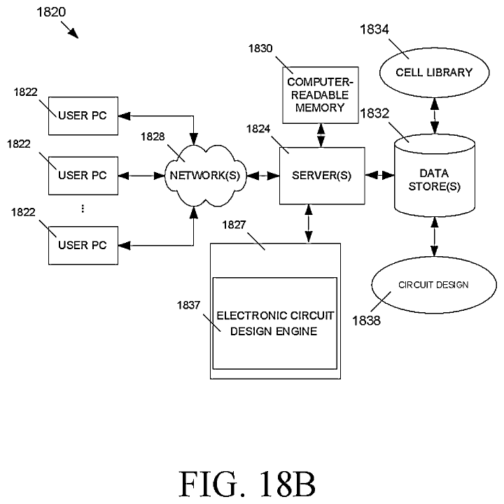

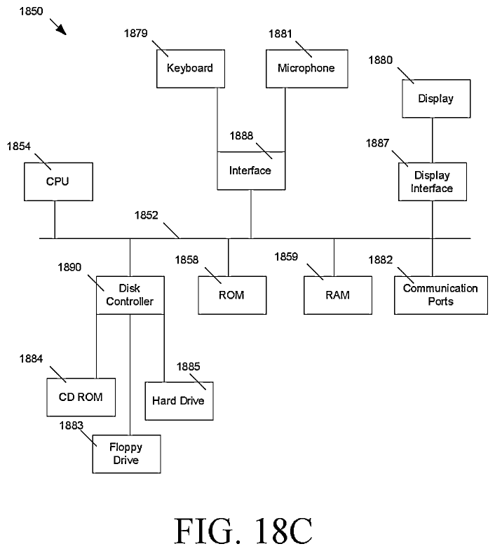

FIGS. 18A, 18B, and 18C depict example systems for implementing the approaches described herein for designing integrated circuits. For example, FIG. 18A depicts an exemplary system 1800 that includes a standalone computer architecture where a processing system 1802 (e.g., one or more computer processors located in a given computer or in multiple computers that may be separate and distinct from one another) includes a computer-implemented electronic circuit design engine 1804 being executed on the processing system 1802. The processing system 1802 has access to a computer-readable memory 1807 in addition to one or more data stores 1808. The one or more data stores 1808 may include a cell library database 1810 as well as a circuit design database 1812. The processing system 1802 may be a distributed parallel computing environment, which may be used to handle very large-scale data sets.

FIG. 18B depicts a system 1820 that includes a client-server architecture. One or more user PCs 1822 access one or more servers 1824 running an electronic circuit design engine 1837 on a processing system 1827 via one or more networks 1828. The one or more servers 1824 may access a computer-readable memory 1830 as well as one or more data stores 1832. The one or more data stores 1832 may include a cell library database 1834 as well as a circuit design database 1838.

FIG. 18C shows a block diagram of exemplary hardware for a standalone computer architecture 1850, such as the architecture depicted in FIG. 18A that may be used to include and/or implement the program instructions of system embodiments of the present disclosure. A bus 1852 may serve as the information highway interconnecting the other illustrated components of the hardware. A processing system 1854 labeled CPU (central processing unit) (e.g., one or more computer processors at a given computer or at multiple computers), may perform calculations and logic operations required to execute a program. A non-transitory processor-readable storage medium, such as read only memory (ROM) 1858 and random-access memory (RAM) 1859, may be in communication with the processing system 1854 and may include one or more programming instructions for performing the method of designing an integrated circuit. Optionally, program instructions may be stored on a non-transitory computer-readable storage medium such as a magnetic disk, optical disk, recordable memory device, flash memory, or other physical storage medium.

In FIGS. 18A, 18B, and 18C, computer readable memories 1807, 1830, 1858, 1859 or data stores 1808, 1832, 1883, 1884, 1888 may include one or more data structures for storing and associating various data used in the example systems for designing an integrated circuit. For example, a data structure stored in any of the aforementioned locations may be used to store data from XML files, initial parameters, and/or data for other variables described herein. A disk controller 1890 interfaces one or more optional disk drives to the system bus 1852. These disk drives may be external or internal floppy disk drives such as 1883, external or internal CD-ROM, CD-R, CD-RW, or DVD drives such as 1884, or external or internal hard drives 1885. In addition to physical drives, the system bus 1852 may be in communication with cloud-based virtual drives. As indicated previously, these various disk drives and disk controllers are optional devices.

Each of the element managers, real-time data buffer, conveyors, file input processor, database index shared access memory loader, reference data buffer and data managers may include a software application stored in one or more of the disk drives connected to the disk controller 1890, the ROM 1858 and/or the RAM 1859. The processor 1854 may access one or more components as required. A display interface 1887 may permit information from the bus 1852 to be displayed on a display 1880 in audio, graphic, or alphanumeric format. Communication with external devices may optionally occur using various communication ports 1882. In addition to these computer-type components, the hardware may also include data input devices, such as a keyboard 1879, or other input device 1881, such as a microphone, remote control, pointer, mouse and/or joystick.

Additionally, the methods and systems described herein may be implemented on many different types of processing devices by program code comprising program instructions that are executable by the device processing subsystem. The software program instructions may include source code, object code, machine code, or any other stored data that is operable to cause a processing system to perform the methods and operations described herein and may be provided in any suitable language such as C. C++, JAVA, for example, or any other suitable programming language. Other implementations may also be used, however, such as firmware or even appropriately designed hardware configured to carry out the methods and systems described herein.

The systems' and methods' data (e.g., associations, mappings, data input, data output, intermediate data results, final data results, etc.) may be stored and implemented in one or more different types of computer-implemented data stores, such as different types of storage devices and programming constructs (e.g., RAM, ROM, Flash memory, flat files, databases, programming data structures, programming variables, IF-THEN (or similar type) statement constructs, etc.). It is noted that data structures describe formats for use in organizing and storing data in databases, programs, memory, or other computer-readable media for use by a computer program.

The computer components, software modules, functions, data stores and data structures described herein may be connected directly or indirectly to each other in order to allow the flow of data needed for their operations. It is also noted that a module or processor includes but is not limited to a unit of code that performs a software operation, and can be implemented for example as a subroutine unit of code, or as a software function unit of code, or as an object (as in an object-oriented paradigm), or as an applet, or in a computer script language, or as another type of computer code. The software components and/or functionality may be located on a single computer or distributed across multiple computers depending upon the situation at hand.

Designs, systems, and methods are described herein. In an example method of fabricating an integrated circuit, an input design is received. From the input design, a layout design comprising a plurality of functional cells and a plurality of spare cells is generated. A plurality of flexible pin extensions are generated to connect to pins of the spare cells, wherein the plurality of flexible pin extensions comprises a plurality of segments formed on different layer levels of the design layout. The method further comprises performing a routing to interconnect functional cells in the design layout and generate a routed design and fabricating an integrated circuit according to the routed design.

In another example, a method of designing an integrated circuit comprises generating a plurality of functional cells and generating a plurality of spare cells configured to an enable an engineering change order. A first spare cell of the plurality of spare cells comprises a plurality of pins in a first layer level. The method further comprises generating at least one flexible pin extension electrically connected to a first pin of the plurality of pins, wherein the at least one flexible pin extension comprises a plurality of segments located in layer levels different from the first layer level. In the example method, the plurality of functional cells is routed into nets.

In an example method of designing a spare cell, a plurality of pins that are disposed in a first layer level are generated, and a first flexible pin extension is generated to connect to a first pin of the plurality of pins. Generating the first flexible pin extension comprises generating a first segment located outside of the cell boundary and disposed in a second layer level.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

It is claimed:

1. A method of fabricating an integrated circuit, comprising:
receiving an input design;
generating a design layout comprising a plurality of functional cells and a plurality of spare cells, wherein each spare cell of the plurality of spare cells comprises a plurality of pins;
generating a plurality of flexible pin extensions to connect to pins of the plurality of spare cells, wherein the plurality of flexible pin extensions comprises a plurality of segments formed on different layer levels of the design layout;
performing a routing to interconnect functional cells in the design layout and generate a routed design; and
fabricating an integrated circuit according to the routed design.

2. The method of claim 1, wherein generating the plurality of flexible pin extensions comprises:
assigning layers for segment creation to each pin of the plurality of pins;
generating access points for each assigned layer;
creating segments in each assigned layer based on the generated access points; and
performing a pin routing.

3. The method of claim 2, wherein assigning layers for segment creation comprises:
defining a window around a spare cell of the plurality of spare cells;
generating a layer distribution within the window for each layer;
comparing a density of the layer distribution with a critical density; and
assigning a layer to pins of the spare cell if the density of the layer is greater than the critical density.

4. The method of claim 2, wherein a length of segments created in an assigned layer is based on a pitch of conductive tracks in an adjacent layer.

5. The method of claim 4, wherein a length of a created segment in a second layer directly above a first layer in which pins are disposed is equal to a number of access points generated for the segment multiplied by a pitch of tracks in a third layer directly above the second layer.

6. The method of claim 1, further comprising:
implementing a functional engineering change order (ECO) to generate a second routed design, wherein the ECO comprises performing a second routing to connect at least one spare cell of the plurality of spare cells to at least one functional cell of the plurality of functional cells; and
fabricating a second integrated circuit according to the second routed design.

7. The method of claim 6, wherein a first spare cell of the plurality of spare cells comprises a first pin and a second pin;
a first flexible pin extension of the plurality of flexible pin extensions is connected to the first pin, and a second flexible pin extension of the plurality of flexible pin extensions is connected to the second pin; and
prior to implementing the functional ECO, the first pin is connected to ground through the first flexible pin extension and the second pin is connected to ground through the second flexible pin extension.

8. The method of claim 6, wherein after implementing the functional ECO, one of the first pin and the second pin is not connected to ground and is connected to a first functional cell of the plurality of functional cells.

9. A method of designing an integrated circuit, comprising:
generating a plurality of functional cells; and
generating a plurality of spare cells configured to enable an engineering change order, wherein a first spare cell of the plurality of spare cells comprises a plurality of pins in a first layer level;
generating at least one flexible pin extension electrically connected to a first pin of the plurality of pins, wherein the at least one flexible pin extension comprises a plurality of segments located in layer levels different from the first layer level; and
routing the plurality of functional cells into nets.

10. The method of claim 9, wherein the first pin is connected to ground via the at least one flexible pin extension.

11. The method of claim 9, wherein the segments of the at least one flexible pin extension comprise a first geometry;
a second spare cell of the plurality of spare cells comprises a second flexible pin extension electrically connected to a pin of the second spare cell;
the second flexible pin extension comprises a second plurality of segments having a second geometry; and
the first geometry is the same as the second geometry.

12. The method of claim 9, wherein a segment of the plurality of segments located in a highest layer level is connected to ground.

13. The method of claim 9, further comprising accepting an engineering change order; and
connecting the first pin to a first functional cell of the plurality of functional cells via the at least one flexible pin extension in response to the engineering change order.

14. The method of claim 9, further comprising generating a second flexible pin extension connected to a second pin of the first spare cell,
wherein the second pin is electrically connected to a second functional cell of the plurality of functional cells via the second flexible pin extension.

15. A method of designing a spare cell, comprising:
generating a plurality of pins disposed in a first layer level; and
generating a first flexible pin extension to connect to a first pin of the plurality of pins,
wherein generating the first flexible pin extension comprises generating first segment located outside of the boundary of the cell and disposed in a second layer level.

16. The method of claim 15, wherein generating the first flexible pin extension comprises generating a plurality of segments;
the first segment is an uppermost segment of the plurality of segments; and
the first segment is connected to ground.

17. The method of claim 15, further comprising generating a design layout comprising the spare cell and plurality of functional cells,
wherein the first flexible pin extension enables the first pin to be connected to a first functional cell of the plurality of functional cells in response to an engineering change order.

18. The method of claim 15, wherein the first pin is extended beyond the cell boundary by an extension segment in the first layer level;
the second layer level is directly above the first layer level; and
the extension segment is connected to the first segment by a first conductive via.

19. The method of claim 18, wherein generating the at least one flexible pin extension further comprises:
generating a second segment located in a third layer level, wherein the third layer level is directly above the second layer level; and
the first segment is connected to the third segment by a second conductive via.

20. The method of claim 19, further comprising generating a second flexible pin extension connected to a second pin of the plurality of pins,
wherein the design layout comprises a plurality of functional cells;
the first pin is electrically connected to ground via the first segment; and
the second pin is electrically connected to a first functional cell of the plurality of functional cells via the second flexible pin extension.
